(19) United States
(12) Patent Application Publication
(10) Pub. No.: US 2011/0012091 A1
(43) Pub. Date: Jan. 20, 2011

(54) ENHANCEMENT OF ORGANIC PHOTOVOLTAIC CELL OPEN CIRCUIT VOLTAGE USING ELECTRON/HOLE BLOCKING EXCITON BLOCKING LAYERS

(75) Inventors: Stephen R. Forrest, Ann Arbor, MI (US); Ning Li, Ann Arbor, MI (US)

Correspondence Address: MCDERMOTT WILL & EMERY LLP, 2049 CENTURY PARK EAST, 38th Floor, LOS ANGELES, CA, 90067-3208, US

(73) Assignee: THE REGENTS OF THE UNIVERSITY OF MICHIGAN, Ann Arbor, MI (US)

(21) Appl. No.: 12/686,305

(22) Filed: Jan. 12, 2010

Related U.S. Application Data
(60) Provisional application No. 61/144,043, filed on Jan. 12, 2009.

(51) Int. Cl. H01L 51/42

(52) U.S. Cl. 257/40; 257/E51.026

(57) ABSTRACT

The present disclosure relates to photosensitive optoelectronic devices comprising at least one of an electron blocking or hole blocking layer. Further disclosed are methods of increasing power conversion efficiency in photosensitive optoelectronic devices using at least one of an electron blocking or hole blocking layer. The electron blocking and hole blocking layers presently disclosed may reduce electron leakage current by reducing the dark current components of photovoltaic cells. This work demonstrates the importance of reducing dark current to improve power conversion efficiency of photovoltaic cells.

### CROSS-REFERENCE TO RELATED APPLICATION

This application claims priority to U.S. Provisional Application No. 61/144,043, filed on Jan. 12, 2009, which is incorporated herein by reference in its entirety.

### STATEMENT REGARDING FEDERALLY SPONSORED RESEARCH

This invention was made with U.S. Government support under FA9550-07-1-0364 awarded by the U.S. Air Force Office of Scientific Research, and DE-FG36-08GO18022 awarded by the U.S. Department of Energy. The government has certain rights in the invention.

### JOINT RESEARCH AGREEMENT

The claimed invention was made by, on behalf of, and/or in connection with one or more of the following parties to a joint university-corporation research agreement: University of Michigan and Global Photonic Energy Corporation. The agreement was in effect on and before the date the invention was made, and the claimed invention was made as a result of activities undertaken within the scope of the agreement.

### FIELD OF THE DISCLOSURE

The present disclosure generally relates to photosensitive optoelectronic devices comprising at least one blocking layer, chosen from electron blocking and hole blocking layers. The present disclosure also relates to methods of increasing power conversion efficiency in photosensitive optoelectronic devices using at least one the blocking layers described herein. The electron blocking layer and hole blocking layer of the devices presently disclosed may provide for reduced dark current and increase open circuit voltage.

### BACKGROUND

Optoelectronic devices rely on the optical and electronic properties of materials to either produce or detect electromagnetic radiation electronically or to generate electricity from ambient electromagnetic radiation.

Photosensitive optoelectronic devices convert electromagnetic radiation into electricity. Solar cells, also called photovoltaic (PV) devices, are a type of photosensitive optoelectronic device that is specifically used to generate electrical power. PV devices, which may generate electrical energy from light sources other than sunlight, can be used to drive power consuming loads to provide, for example, lighting, heating, or to power electronic circuitry or devices such as calculators, radios, computers or remote monitoring or communications equipment. These power generation applications also often involve the charging of batteries or other energy storage devices so that operation may continue when direct illumination from the sun or other light sources is not available, or to balance the power output of the PV device with a specific application's requirements. As used herein the term “resistive load” refers to any power consuming or storing circuit, device, equipment or system.

Another type of photosensitive optoelectronic device is a photoconductor cell. In this function, signal detection circuitry monitors the resistance of the device to detect changes due to the absorption of light.

Another type of photosensitive optoelectronic device is a photodetector. In operation a photodetector is used in conjunction with a current detecting circuit which measures the current generated when the photodetector is exposed to electromagnetic radiation and may have an applied bias voltage. A detecting circuit as described herein is capable of providing a bias voltage to a photodetector and measuring the electronic response of the photodetector to electromagnetic radiation.

These three classes of photosensitive optoelectronic devices may be characterized according to whether a rectifying junction as defined below is present and also according to whether the device is operated with an external applied voltage, also known as a bias or bias voltage. A photoconductor cell does not have a rectifying junction and is normally operated with a bias. A PV device has at least one rectifying junction and is operated with no bias. A photodetector has at least one rectifying junction and is usually but not always operated with a bias. As a general rule, a photovoltaic cell provides power to a circuit, device or equipment, but does not provide a signal or current to control detection circuitry, or the output of information from the detection circuitry. In contrast, a photodetector or photoconductor provides a signal or current to control detection circuitry, or the output of information from the detection circuitry but does not provide power to the circuitry, device or equipment.

Traditionally, photosensitive optoelectronic devices have been constructed of a number of inorganic semiconductors, e.g., crystalline, polycrystalline and amorphous silicon, gallium arsenide, cadmium telluride and others. Herein the term “semiconductor” denotes materials which can conduct electricity when charge carriers are induced by thermal or electromagnetic excitation. The term “photoconductive” generally relates to the process in which electromagnetic radiant energy is absorbed and thereby converted to excitation energy of electric charge carriers so that the carriers can conduct, i.e., transport, electric charge in a material. The terms “photoconductor” and “photoconductive material” are used herein to refer to semiconductor materials which are chosen for their property of absorbing electromagnetic radiation to generate electric charge carriers.

PV devices may be characterized by the efficiency with which they can convert incident solar power to useful electric power. Devices utilizing crystalline or amorphous silicon dominate commercial applications, and some have achieved efficiencies of 23% or greater. However, efficient crystalline-based devices, especially of large surface area, are difficult and expensive to produce due to the problems inherent in producing large crystals without significant efficiency-degrading defects. On the other hand, high efficiency amorphous silicon devices still suffer from problems with stability. Present commercially available amorphous silicon cells have stabilized efficiencies between 4 and 8%. More recent efforts have focused on the use of organic photovoltaic cells to achieve acceptable photovoltaic conversion efficiencies with economical production costs.

PV devices may be optimized for maximum electrical power generation under standard illumination conditions (i.e., Standard Test Conditions which are 1000 W/m², AM1.5 spectral illumination), for the maximum product of photocurrent times photovoltage. The power conversion efficiency of such a cell under standard illumination conditions depends on the following three parameters: (1) the current under zero bias, i.e., the short-circuit current I_{SC}, in Amperes (2) the photovoltage under open circuit conditions, i.e., the open circuit voltage V_{OC}, in Volts and (3) the fill factor, ff.

PV devices produce a photo-generated current when they are connected across a load and are irradiated by light. When irradiated under infinite load, a PV device generates its maximum possible voltage, V open-circuit, or V_{OC}. When irradiated with its electrical contacts shorted, a PV device generates its maximum possible current, I short-circuit, or I_{SC}. When actually used to generate power, a PV device is connected to a finite resistive load and the power output is given by the product of the current and voltage, I×V. The maximum total power generated by a PV device is inherently incapable of exceeding the product, I_{SC}×V_{OC}. When the load value is optimized for maximum power extraction, the current and voltage have the values, Iₘₐₓ and Vₘₐₓ, respectively.

A figure of merit for PV devices is the fill factor, ff; defined as:

ff={IₘₐₓVₘₐₓ}/{I_{SC}V_{OC}}

where ff is always less than 1, as I_{SC} and V_{OC} are never obtained simultaneously in actual use. Nonetheless, as ff approaches 1, the device has less series or internal resistance and thus delivers a greater percentage of the product of I_{SC} and V_{OC} to the load under optimal conditions. Where P_{inc} is the power incident on a device, the power efficiency of the device, η_{P}, may be calculated by:

η_{P}=ff*(I_{SC}*V_{OC})/P_{inc}

When electromagnetic radiation of an appropriate energy is incident upon a semiconductive organic material, for example, an organic molecular crystal (OMC) material, or a polymer, a photon can be absorbed to produce an excited molecular state. This is represented symbolically as S₀+hv [symbol] S₀*. Here S₀ and S₀* denote ground and excited molecular states, respectively. This energy absorption is associated with the promotion of an electron from a bound state in the highest occupied molecular orbital (HOMO) energy level, which may be a B-bond, to the lowest unoccupied molecular orbital (LUMO) energy level, which may be a B*-bond, or equivalently, the promotion of a hole from the LUMO energy level to the HOMO energy level. In organic thin-film photoconductors, the generated molecular state is generally believed to be an exciton, i.e., an electron-hole pair in a bound state which is transported as a quasi-particle. The excitons can have an appreciable life-time before geminate recombination, which refers to the process of the original electron and hole recombining with each other, as opposed to recombination with holes or electrons from other pairs. To produce a photocurrent the electron-hole pair becomes separated, typically at a donor-acceptor interface between two dissimilar contacting organic thin films. If the charges do not separate, they can recombine in a geminant recombination process, also known as quenching, either radiatively, by the emission of light of a lower energy than the incident light, or non-radiatively, by the production of heat. Either of these outcomes is undesirable in a photosensitive optoelectronic device.

Electric fields or inhomogeneities at a contact may cause an exciton to quench rather than dissociate at the donor-acceptor interface, resulting in no net contribution to the current. Therefore, it is desirable to keep photogenerated excitons away from the contacts. This has the effect of limiting the diffusion of excitons to the region near the junction so that the associated electric field has an increased opportunity to separate charge carriers liberated by the dissociation of the excitons near the junction.

To produce internally generated electric fields which occupy a substantial volume, the usual method is to juxtapose two layers of material with appropriately selected conductive properties, especially with respect to their distribution of molecular quantum energy states. The interface of these two materials is called a photovoltaic heterojunction. In traditional semiconductor theory, materials for forming PV heterojunctions have been denoted as generally being of either n or p type. Here n-type denotes that the majority carrier type is the electron. This could be viewed as the material having many electrons in relatively free energy states. The p-type denotes that the majority carrier type is the hole. Such material has many holes in relatively free energy states. The type of the background, i.e., not photo-generated, majority carrier concentration depends primarily on unintentional doping by defects or impurities. The type and concentration of impurities determine the value of the Fermi energy, or level, within the gap between the highest occupied molecular orbital (HOMO) energy level and the lowest unoccupied molecular orbital (LUMO) energy level, called the HOMO-LUMO gap. The Fermi energy characterizes the statistical occupation of molecular quantum energy states denoted by the value of energy for which the probability of occupation is equal to ½. A Fermi energy near the LUMO energy level indicates that electrons are the predominant carrier. A Fermi energy near the HOMO energy level indicates that holes are the predominant carrier. Accordingly, the Fermi energy is a primary characterizing property of traditional semiconductors and the prototypical PV heterojunction has traditionally been the p-n interface.

The term “rectifying” denotes, inter alia, that an interface has an asymmetric conduction characteristic, i.e., the interface supports electronic charge transport preferably in one direction. Rectification is associated normally with a built-in electric field which occurs at the heterojunction between appropriately selected materials.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

In the context of organic materials, the terms “donor” and “acceptor” refer to the relative positions of the HOMO and LUMO energy levels of two contacting but different organic materials. This is in contrast to the use of these terms in the inorganic context, where “donor” and “acceptor” may refer to types of dopants that may be used to create inorganic n- and p-types layers, respectively. In the organic context, if the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

A significant property in organic semiconductors is carrier mobility. Mobility measures the ease with which a charge carrier can move through a conducting material in response to an electric field. In the context of organic photosensitive devices, a layer including a material that conducts preferentially by electrons due to a high electron mobility may be referred to as an electron transport layer, or ETL. A layer including a material that conducts preferentially by holes due to a high hole mobility may be referred to as a hole transport layer, or HTL. Preferably, but not necessarily, an acceptor material is an ETL and a donor material is a HTL.

Conventional inorganic semiconductor PV cells employ a p-n junction to establish an internal field. Early organic thin film cell, such as reported by Tang, Appl. Phys Lett. 48, 183 (1986), contain a heterojunction analogous to that employed in a conventional inorganic PV cell. However, it is now recognized that in addition to the establishment of a p-n type junction, the energy level offset of the heterojunction also plays an important role.

The energy level offset at the organic D-A heterojunction is believed to be important to the operation of organic PV devices due to the fundamental nature of the photogeneration process in organic materials. Upon optical excitation of an organic material, localized Frenkel or charge-transfer excitons are generated. For electrical detection or current generation to occur, the bound excitons must be dissociated into their constituent electrons and holes. Such a process can be induced by the built-in electric field, but the efficiency at the electric fields typically found in organic devices (F˜10⁶ V/cm) is low. The most efficient exciton dissociation in organic materials occurs at a donor-acceptor (D-A) interface. At such an interface, the donor material with a low ionization potential forms a heterojunction with an acceptor material with a high electron affinity. Depending on the alignment of the energy levels of the donor and acceptor materials, the dissociation of the exciton can become energetically favorable at such an interface, leading to a free electron polaron in the acceptor material and a free hole polaron in the donor material.

Organic PV cells have many potential advantages when compared to traditional silicon-based devices. Organic PV cells are light weight, economical in materials use, and can be deposited on low cost substrates, such as flexible plastic foils. However, organic PV devices typically have relatively low external quantum efficiency (electromagnetic radiation to electricity conversion efficiency), being on the order of 1% or less. This is, in part, thought to be due to the second order nature of the intrinsic photoconductive process. That is, carrier generation requires exciton generation, diffusion and ionization or collection. There is an efficiency ηassociated with each of these processes. Subscripts may be used as follows: P for power efficiency, EXT for external quantum efficiency, A for photon absorption, ED for diffusion, CC for collection, and INT for internal quantum efficiency. Using this notation:

η_{P}˜η_{EXT}=η_{A}*η_{ED}*η_{CC}

η_{EXT}=η_{A}*η_{INT}

The diffusion length (L_{D}) of an exciton is typically much less (L_{D}˜50Δ) than the optical absorption length (˜500Δ), requiring a trade-off between using a thick, and therefore resistive, cell with multiple or highly folded interfaces, or a thin cell with a low optical absorption efficiency.

The power conversion efficiency may be expressed as

$${η}_{p} = \frac{{V}_{OC} \cdot FF \cdot {J}_{SC}}{{P}_{0}} ,$$

where V_{OC} is the open circuit voltage, FF is the fill factor, J_{sc} is the short circuit current, and P₀ is the input optical power. One way to improve ηₚ is through the enhancement of V_{oc}, which is still 3-4 times less than the typical absorbed photon energy in most organic PV cells. The relationship between dark current and V_{oc} may be inferred from:

$$J = \frac{{R}_{p}}{{R}_{S} + {R}_{P}} \{ {J}_{S} [ exp ( \frac{q ( V - {JR}_{S}}{nkT} ) - 1 ] + \frac{V}{{R}_{P}} \} - {J}_{p h} ( V ) \qquad ( 1 )$$

where J is the total current, Jₛ is the reverse dark saturation current, n is the ideality factor, Rₛ is the series resistance, Rₚ is the parallel resistance, V is the bias voltage, and Jₚₕ is the photocurrent (Rand et al., Phys. Rev. B, vol. 75, 115327 (2007)). Setting J=0:

$${V}_{OC} = \frac{nkT}{q} ln ( \frac{{J}_{p h} ( {V}_{OC} )}{{J}_{S}} + 1 - \frac{{V}_{OC}}{{R}_{p} {J}_{z}} ) \qquad ( 2 )$$

when Jₚₕ/Jₛ>>I, V_{OC} is proportional to In(Jₚₕ/Jₛ), suggesting that a large dark current, Jₛ, results in a reduction in V_{OC}.

As described herein, high dark current in PV cells may result in a significant reduction in their power conversion efficiency. The dark current in an organic PV cell may come from several sources. At forward bias, the dark current consists of (1) the generation/recombination current I_{gr} due to the electron-hole recombination at donor/acceptor interface, (2) the electron leakage current Iₑ due to electrons going from an active donor-acceptor region of the cell to the anode, not from an external source, and (3) the hole leakage current Iₕ due to holes formed in a donor-acceptor region of the cell moving to the cathode. FIG. 2. illustrates the various components of dark current and the related energy levels. The magnitudes of these current components are strongly dependent on the energy levels. I_{gr}, increases with the decrease of the donor-acceptor interfacial energy gap, which is the difference of the lowest unoccupied molecular orbital (LUMO) of the acceptor and the highest occupied molecular orbital (HOMO) of the donor (ΔEg). Iₑ increases with the decrease of ΔE_{L}, which is the difference of the lowest unoccupied molecular orbital (LUMO) energies of the donor and acceptor. Iₕ increases with the decrease of ΔE_{H}, which is the difference of the highest occupied molecular orbital (HOMO) energies of the donor and acceptor. Any of these three current components can be the dominating dark current depending on the energy levels of the donor and acceptor materials.

For example, in a tin phthalocyanine (SnPC)/C₆₀ PV cell, ΔE_{L} is 0.2 eV. The energy barrier for electron to go from the acceptor to the donor is low, leading to a dominant electron leakage current Iₑ at dark. In a copper phthalocyanine (CuPc)/C₆₀ cell, ΔE_{L} is 0.8 eV, leading to a negligible electron leakage current Iₑ, such that the generation/recombination current I_{gr} is the dominant dark current source. The hole leakage current Iₕ is usually small, due to the relatively large ΔE_{H} in most commonly used donor/acceptor pairs.

Among small molecule organic materials, tin (II) phthalocyanine (SnPc) has demonstrated significant absorption at wavelengths from λ=600 nm to 900 nm, with a cut off λ=1000 nm. Indeed, approximately 50% of the total solar photon flux is in the red and near-infrared (NIR) spectrum at wavelengths from λ=600 nm to 100 nm. However, long wavelength absorbing materials such as SnPc generally result in cells with low V_{OC}. A 50 Å thick, discontinuous layer of SnPc has been included between a CuPc/C₆₀ heterojunction to expand the absorption spectral range of an otherwise short wavelength (λ<700 nm) sensitive photovoltaic cell. (Rand et al., Appl. Phys. Lett., 87, 233508 (2005).) Alternatively, SnPc has been grown into discontinuous islands between CuPc and C₆₀ to achieve long wavelength sensitivity. (Yang et al., Appl. Phys. Lett. 92, 053310 (2008).) A SnPc tandem cell using C₇₀ as the acceptor material has also been reported. (Inoue et al., J. Cryst. Growth, 298, 782-786 (2007).)

Exciton blocking layers that also function as electron blocking layers have been developed for polymer Bulk Heterojunction (BHJ) PV cells (Hains et al., Appl. Phys. Lett., vol. 92, 023504 (2008)). In polymer BHJ PV cells, blended polymers of donor and acceptor materials are used as the active region. These blends can have regions of donor or acceptor material extending from one electrode to the other. Therefore, there can be electron or hole conduction pathways between the electrodes through one type of polymer molecule.

Besides polymer BHJ PV cells, other architectures, including planar PV devices, also exhibit a significant electron or hole leakage current across the donor/acceptor heterojunction when ΔE_{L} or ΔE_{H} is small, even though these films may not have single material (donor or acceptor) pathways between the two electrodes.

The present disclosure relates to increased power conversion efficiency of photosensitive optoelectronic devices through use of electron blocking layers that block electrons and/or hole blocking layers that block holes. The present disclosure further relates to the dark current components of PV cells, and their dependence on the energy level alignment of PV cells comprising planar films. Also disclosed are methods of increasing power conversion efficiency photosensitive optoelectronic devices by using an electron blocking and/or hole blocking layers.

### SUMMARY OF THE DISCLOSURE

The present disclosure is directed to an organic photosensitive optoelectronic device comprising: two electrodes comprising an anode and a cathode in superposed relation; at least one donor material and at least one acceptor material, wherein the donor material and acceptor material form a photo-active region between the two electrodes; at least one electron blocking layer or hole blocking layer located between the two electrodes, wherein the electron blocking layer and the hole blocking layer comprise at least one material chosen from organic semiconductors, inorganic semiconductors, polymers, metal oxides, or combinations thereof.

Non-limiting examples of the electron blocking layer used herein include at least one organic semiconducting material, such as those chosen from tris-(8-hydroxyquinolinato)aluminium(III) (Alq3), N,N′-bis(3-methylphenyl)-(1,1′-biphenyl)-4′-diamine (TPD), 4,4′-bis[N-(naphthyl)-N-phenyl-amino]biphenyl (NPD), subphthalocyanine (SubPc), pentacene, squaraine, copper phthalocyanine (CuPc), zinc phthalocyanine (ZnPc), chloroaluminum phthalocyanine (ClAlPc), tris(2-phenylpyridine) (Ir(ppy)₃).

Non-limiting examples of the at least one metal oxide of that can be used as electron blocking layer include oxides of Cu, Al, Sn, Ni, W, Ti, Mg, In, Mo, Zn, and combinations thereof, such as NiO, MoO₃, CuAlO₂. Other inorganic materials that could be used as an electron blocking layer include allotropes of carbon, such as diamond and carbon nanotubes, and MgTe.

Non-limiting examples of the at least one inorganic semiconductor material that can be used as electron blocking layer include Si, II-VI, and III-V semiconductor materials.

Non-limiting examples of the at least one hole blocking layer comprises at least one organic semiconducting material chosen from naphthalene tetracarboxylic anhydride (NTCDA), p-bis(triphenylsilyl)benzene (UGH2), 3,4,9,10-perylenetetracarboxylic dianhydride (PTCDA), and 7,7,8,8,-tetracyanonequinodimethane (TCNQ).

The hole blocking layer may also comprise inorganic materials, non-limiting examples of which include TiO₂, GaN, ZnS, ZnO, ZnSe, SrTiO₃, KaTiO₃, BaTiO₃, MnTiO₃, PbO, WO₃, SnO₂.

The present disclosure is directed to an organic photosensitive optoelectronic device comprising: two electrodes comprising an anode and a cathode in superposed relation; at least one donor material, such as at least one material chosen from CuPc, SnPc, and squaraine and at least one acceptor material, such as C₆₀ and/or PTCBI, wherein the donor material and acceptor material form a photo-active region between the two electrodes; at least one electron blocking EBL or hole blocking EBL located between the two electrodes.

In one embodiment, there is disclosed an organic photosensitive optoelectronic device in which the at least one electron blocking EBL comprises at least one material chosen from tris-(8-hydroxyquinolinato)aluminium(III) (Alq3), N,N′-bis(3-methylphenyl)-(1,1′-biphenyl)-4′-diamine (TPD), 4,4′-bis[N-(naphthyl)-N-phenyl-amino]biphenyl (NPD), subphthalocyanine (SubPc), copper phthalocyanine (CuPc), zinc phthalocyanine (ZnPc), chloroaluminum phthalocyanine (ClAlPc), tris(2-phenylpyridine) (Ir(ppy)₃), and MoO₃, and

the at least one hole blocking EBL comprises at least one material chosen from naphthalene tetracarboxylic anhydride (NTCDA), p-bis(triphenylsilyl)benzene (UGH2), 3,4,9,10-perylenetetracarboxylic dianhydride (PTCDA), and 7,7,8,8,-tetracyanonequinodimethane (TCNQ).

With regard to the location of the disclosed blocking layers, the electron blocking EBL may be adjacent to the donor region and the hole blocking EBL may be adjacent to the acceptor region. It is also understood that it is possible to fabricate a device that comprises both an electron blocking EBL and a hole blocking EBL.

In one embodiment, the first photoconductive organic semiconductor material and the second photoconductive organic semiconductor material are selected to have spectral sensitivity in the visible spectrum. It is understood that the first photoconductive organic semiconductor material and the second photoconductive organic semiconductor material may be at least partially mixed.

In one embodiment, the donor region comprises at least one material chosen from CuPc and SnPc, the acceptor region comprises C₆₀, and the electron blocking EBL comprises MoO₃.

The device described herein may be an organic photodetector or an organic solar cell.

The present disclosure is further directed to a stacked organic photosensitive optoelectronic device comprising a plurality of photosensitive optoelectronic subcells wherein at least one subcell comprises two electrodes comprising an anode and a cathode in superposed relation; at least one donor material, such as at least one material chosen from CuPc, SnPc, and squaraine and at least one acceptor material, such as C₆₀ and/or PTCBI, wherein the donor material and acceptor material form a photo-active region between the two electrodes; at least one electron blocking EBL or hole blocking EBL located between the two electrodes.

As described above, in the stacked organic photosensitive device described herein the at least one electron blocking EBL comprises at least one material chosen from tris-(8-hydroxyquinolinato)aluminium(III) (Alq3), N,N′-bis(3-methylphenyl)-(1,1′-biphenyl)-4′-diamine (TPD), 4,4′-bis[N-(naphthyl)-N-phenyl-amino]biphenyl (NPD), subphthalocyanine (SubPc), copper phthalocyanine (CuPc), zinc phthalocyanine (ZnPc), chloroaluminum phthalocyanine (ClAlPc), tris(2-phenylpyridine) (Ir(ppy)₃), and MoO₃, and

the at least one hole blocking EBL comprises at least one material chosen from naphthalene tetracarboxylic anhydride (NTCDA), p-bis(triphenylsilyl)benzene (UGH2), 3,4,9,10-perylenetetracarboxylic dianhydride (PTCDA), and 7,7,8,8,-tetracyanonequinodimethane (TCNQ).

The present disclosure is further directed to a method of increasing the power conversion efficiency of a photosensitive optoelectronic device comprising incorporating at least one of an electron blocking EBL and a hole blocking EBL described herein to reduce the dark current and increase the open circuit voltage of the device.

Aside from the subject matter discussed above, the present disclosure includes a number of other exemplary features such as those explained hereinafter. It is to be understood that both the foregoing description and the following description are exemplary only.

### BRIEF DESCRIPTION OF THE DRAWINGS

The accompanying figures are incorporated in, and constitute a part of, this specification.

FIG. 1 shows current density vs. voltage characteristics of an ITO/SnPc (400 Å)/C₆₀ (400 Å)/BCP (100 Å)/Al photovoltaic (PV) cell (open squares), and an ITO/CuPc (200 Å)/C₆₀ (400 Å)/BCP (100 Å)/Al PV cell (open triangles), under dark and illumination levels of 0.2 sun and 1 sun, AM1.5 illumination. The dark current fitting results are also shown (solid lines).

FIGS. 2(a) and 2(b) show an energy level diagram of a bi-layer organic photovoltaic cell.

FIG. 3 shows a schematic energy level diagram illustrating (a) the structure of a photovoltaic (PV) cell comprising an electron blocking EBL, and (b) energy levels of materials suitable for electron blocking EBL in SnPc and squaraine PV cells.

FIG. 4 shows a schematic energy level diagram illustrating (a) the structure of a photovoltaic (PV) cell comprising a hole blocking EBL, and (b) energy levels of materials that are suitable for hole blocking EBL in C₆₀ and PTCBI PV cells.

FIG. 5 shows current density vs. voltage characteristics of an ITO/SnPc (100 Å)/C₆₀ (400 Å)/BCP (100 Å)/Al photovoltaic cell without an electron blocking EBL (dashed line), with a MoO₃ electron blocking EBL (open squares), with a SubPc electron blocking EBL (open triangles), and with a CuPc electron blocking EBL (open circles). The energy level diagram for the devices with an electron blocking EBL is shown in the inset. The photocurrent was measured under one sun, AM1.5 illumination. The dark current fitting results are also shown (solid lines).

FIG. 6 shows external quantum efficiency (EQE) vs. wavelength of an ITO/CuPc (200 Å)/C₆₀ (400 Å)/BCP (100 Å)/Al (1000 Å) photovoltaic (PV) cell, an ITO/SnPc (100 Å)/C₆₀ (400 Å)/BCP (100 Å)/Al PV cell without a blocking layer, with a MoO₃ electron blocking EBL, with a SubPc electron blocking EBL, and with a CuPc electron blocking EBL.

### DETAILED DESCRIPTION

As shown, the blocking layers described herein may comprise at least one organic or inorganic material. In either case, the requirements of the blocking layers are the same. The only difference sometimes occurs in the terminology used. For example, the energy levels of organic materials are typically described in terms of HOMO and LUMO levels, while in inorganic materials the energy levels are typically described in terms of valence bands (corresponding to a HOMO levels) and conduction bands (corresponding to LUMO levels).

The present disclosure relates to a photosensitive optoelectronic device comprising at least one blocking layer, such as an electron blocking or hole blocking layer. It is understood that the electron blocking or hole blocking layer may also block excitons, and thus act as an exciton blocking layer (EBL). As used herein, the terms “electron blocking” or “hole blocking” may be used interchangeably alone or in combination with “EBL.”

In one embodiment, the present disclosure relates to an organic photosensitive optoelectronic device comprising: two electrodes comprising an anode and a cathode in superposed relation; a donor region between the two electrodes, the donor region formed of a first photoconductive organic semiconductor material; an acceptor region between the two electrodes and adjacent to the donor region, the acceptor region formed of a second photoconductive organic semiconductor material; and at least one of an electron blocking EBL and a hole blocking HBL between the two electrodes and adjacent to at least one of the donor region and the acceptor region. By inserting an electron blocking EBL and/or hole blocking EBL in the PV cell structure, the cell dark current may be suppressed, leading to a concomitant increase in V_{oc}. The power conversion efficiency of the PV cell may thus be improved.

It is to be understood that the present disclosure generally relates to the use of an electron blocking EBL and/or hole blocking EBL in heterojunction PV cells. In at least one embodiment, the PV cell is a planar heterojunction cell. In another embodiment, is PV cell is a planar-mixed heterojunction cell. In other embodiments of the present disclosure, the PV cell is non-planar. For example, the photo-active region may form at least one of a mixed heterojunction, planar heterojunction, bulk heterojunction, nano crystalline-bulk heterojunction, and hybrid planar-mixed heterojunction.

The device presently disclosed comprises two electrodes comprising an anode and a cathode. Electrodes or contacts are usually metals or “metal substitutes.” Herein the term metal is used to embrace both materials composed of an elementally pure metal, e.g., Al, and also metal alloys which are materials composed of two or more elementally pure metals. Here, the term “metal substitute” refers to a material that is not a metal within the normal definition, but which has the metal-like properties that are desired in certain appropriate applications. Commonly used metal substitutes for electrodes and charge transfer layers include doped wide bandgap semiconductors, for example, transparent conducting oxides such as indium tin oxide (ITO), gallium indium tin oxide (GITO), and zinc indium tin oxide (ZITO). In particular, ITO is a highly doped degenerate n+ semiconductor with an optical bandgap of approximately 3.2 eV rendering it transparent to wavelengths greater than approximately 3900 Å.

Another suitable metal substitute material is the transparent conductive polymer polyanaline (PANI) and its chemical relatives. Metal substitutes may be further selected from a wide range of non-metallic materials, wherein the term “non-metallic” is meant to embrace a wide range of materials provided that the material is free of metal in its chemically uncombined form. When a metal is present in its chemically uncombined form, either alone or in combination with one or more other metals as an alloy, the metal may alternatively be referred to as being present in its metallic form or as being a “free metal.” Thus, the metal substitute electrodes of the present disclosure may sometimes be referred to as “metal-free” wherein the term “metal-free” is expressly meant to embrace a material free of metal in its chemically uncombined form. Free metals typically have a form of metallic bonding that may be thought of as a type of chemical bonding that results from a sea of valence electrons throughout the metal lattice. While metal substitutes may contain metal constituents they are “non-metallic” on several bases. They are not pure free-metals nor are they alloys of free-metals. When metals are present in their metallic form, the electronic conduction band tends to provide, among other metallic properties, a high electrical conductivity as well as a high reflectivity for optical radiation.

Herein, the term “cathode” is used in the following manner. In a non-stacked PV device or a single unit of a stacked PV device under ambient irradiation and connected with a resistive load and with no externally applied voltage, e.g., a solar cell, electrons move to the cathode from the adjacent photoconducting material. Similarly, the term “anode” is used herein such that in a solar cell under illumination, holes move to the anode from the adjacent photoconducting material, which is equivalent to electrons moving in the opposite manner. It will be noted that the terms are used herein anodes and cathodes may be electrodes or charge transfer regions.

In at least one embodiment, the organic photosensitive optoelectronic device comprises at least one photoactive region in which light is absorbed to form an excited state, or “exciton,” which may subsequently dissociate in to an electron and a hole. The dissociation of the exciton will typically occur at the heterojunction formed by the juxtaposition of an acceptor layer and a donor layer comprising the photoactive region.

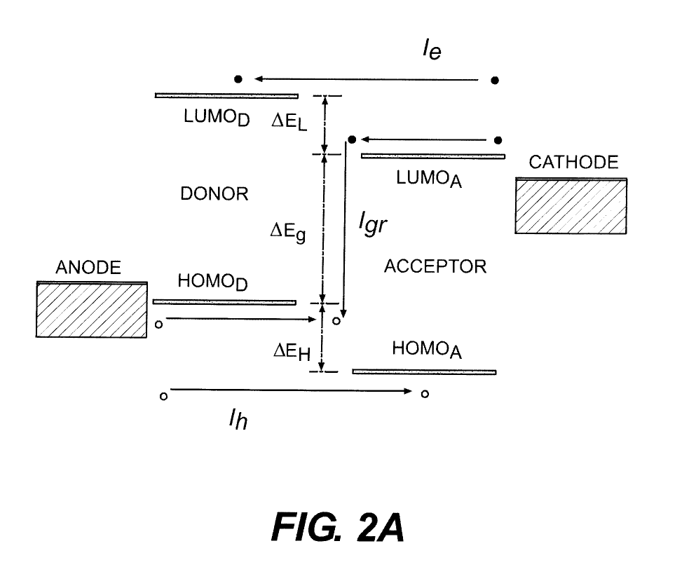

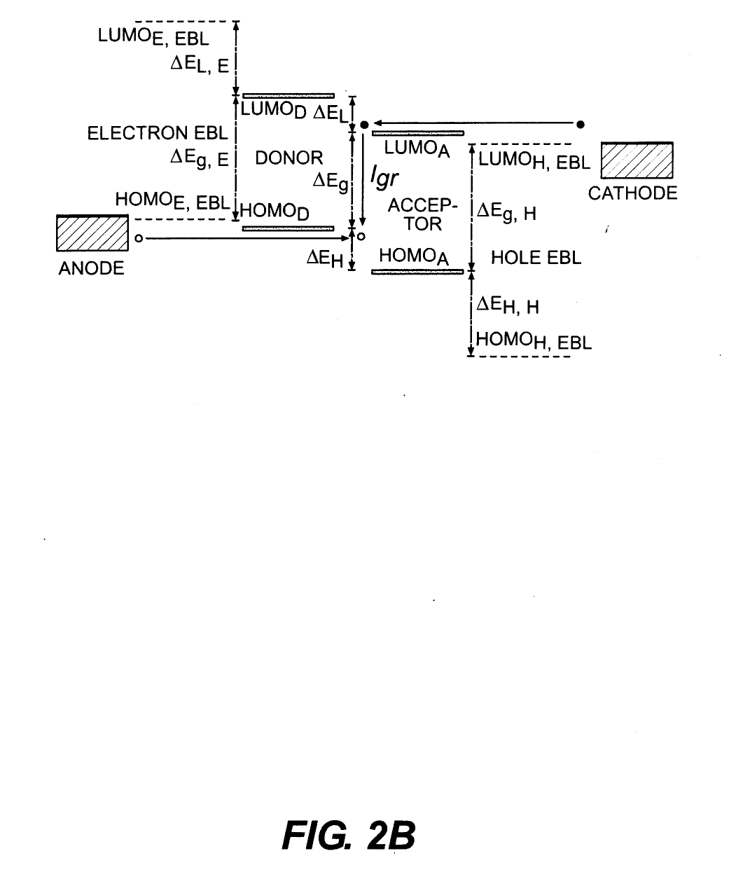

FIG. 2 shows an energy level diagram of a bi-layer donor/acceptor PV cell.

The first photoconductive organic semiconductor material and the second photoconductive organic semiconductor material may be selected to have spectral sensitivity in the visible spectrum.

The photoconductive organic semiconductor material according to the present disclosure may comprise, for example, C₆₀, 4,9,10-perylenetetracarboxylic bis-benzimidazole (PTCBI), squaraine, copper phthalocyanine (CuPc), tin phthalocyanine (SnPc), or boron subphthalocyanine (SubPc). Those skilled in the art will recognize other photoconductive organic semiconductor materials suitable for the present disclosure. In some embodiments, the first photoconductive organic semiconductor material and the second photoconductive organic semiconductor material are at least partially mixed forming mixed, bulk, nanocrystalline-bulk or hybrid planar-mixed or bulk heterojunctions.

When a PV cell is operating under illumination, the output photocurrent is formed by collecting photo-generated electrons at cathode and photo-generated-holes at anode. The dark current flows in the opposite direction due to induced potential drop and electric field. Electrons and holes are injected from cathode and anode, respectively, and can go to the opposite electrodes if they do not encounter significant energy barriers. They can also recombine at the interface to form recombination current. Thermally generated electrons and holes inside the active region can also contribute to the dark current. Although this last component is dominating when the solar cell is reverse biased, it is negligible under forward bias condition.

As described, the dark current of an operating PV cell mainly come from the following sources: (1) the generation/recombination current I_{gr} due to the electron-hole recombination at donor/acceptor interface, (2) the electron leakage current Iₑ due to the electrons going from the cathode to the anode through the donor/acceptor interface, and (3) the hole leakage current Iₕ due to the holes going from the anode to the cathode through the donor/acceptor interface. In operation a solar cell has no externally applied bias. The magnitudes of these current components are dependent on the energy levels. I_{gr} increases with the decrease of interfacial gap ΔE_{g}. Iₑ increases with the decrease of ΔE_{L}, which is the difference of the lowest unoccupied molecular orbital (LUMO) energies of the donor and acceptor. Iₕ increases with the decrease of ΔE_{H}, which is the difference of the highest occupied molecular orbital (HOMO) energies of the donor and acceptor. Any of these three current components can be the dominating dark current depending on the energy levels of the donor and acceptor materials.

Electron Blocking EBL

The electron blocking EBL according to one embodiment of the present disclosure may comprise organic or inorganic materials. In at least one embodiment, the electron blocking EBL is adjacent to the anode. In another embodiment, polymer molecules may be used in PV cells. For example, in one embodiment, the electron blocking EBL at the anode prevents contact of polymer molecules comprising the PV cell and both electrodes. Thus, when used, the polymer comprising PV cell will not be in contact with both electrodes, which may eliminate the electron conduction path. In some embodiments of the present disclosure, the cell has low dark current and high V_{OC}.

In one embodiment, the photo-active region forms at least one of a mixed heterojunction, bulk heterojunction, nano crystalline-bulk heterojunction, and hybrid planar-mixed heterojunction.

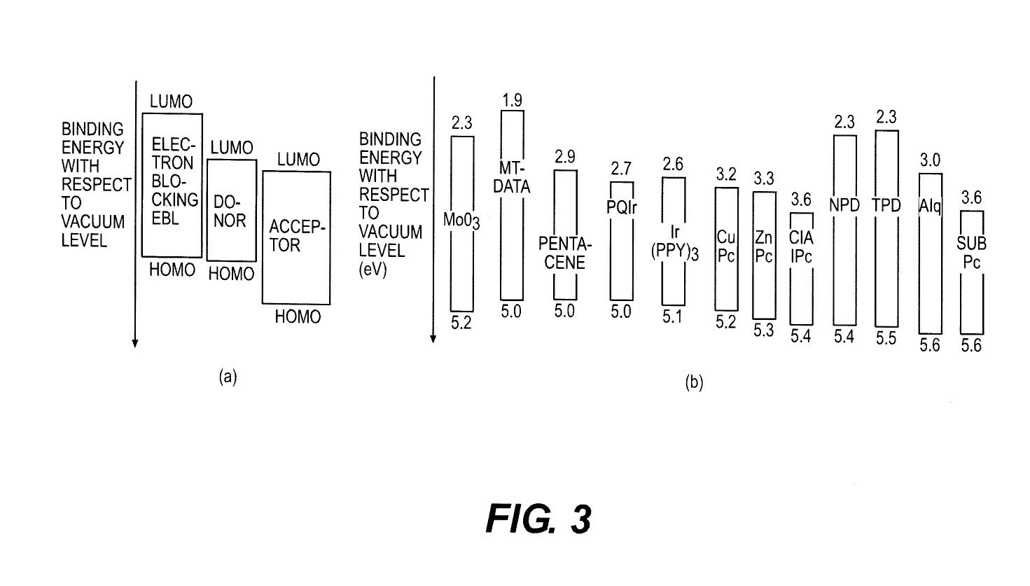

When the electron leakage current Iₑ is dominating in the PV cell, an electron blocking layer may be used to reduce the cell dark current and to increase Voc. FIG. 3(a) shows an energy level diagram of a structure comprising an electron blocking EBL. To efficiently suppress the electron leakage current Iₑ without affecting the hole collection efficiency, the electron blocking EBL should satisfy the following criteria:
1) electron blocking EBL has a higher LUMO energy level than the donor material, such as at least 0.2 eV higher;
2) electron blocking EBL does not introduce a large energy barrier for the hole collection at the electron blocking EBL/donor interface; and
3) electron blocking EBL maintains a large interfacial gap at the interface with the donor material, as indicated by a smaller generation/recombination current than the generation/recombination current between the donor and acceptor, otherwise the generation/recombination current at the electron blocking EBL/donor interface may contribute significantly to the device dark current.

For example, SnPc has a LUMO energy of 3.8 eV below the vacuum level, and a HOMO energy of 5.2 eV. Suitable electron blocking EBL materials in a SnPC/C₆₀ may include, but are not limited to tris-(8-hydroxyquinolinato)aluminium(III) (Alq3), N,N′-bis(3-methylphenyl)-(1,1′-biphenyl)-4′-diamine (TPD), 4,4′-bis[N-(naphthyl)-N-phenyl-amino]biphenyl (NPD), 4,4′,4″-tris(N-(3-methylphenyl)N-phenylamino)triphenylamine (MTDATA), subphthalocyanine (SubPc), copper phthalocyanine (CuPc), zinc phthalocyanine (ZnPc), chloroaluminum phthalocyanine (ClAlPc), tris(2-phenylpyridine)iridium (Ir(ppy)₃), and MoO₃. The energy levels for those materials are shown in FIG. 3(b).

Further, for example, 2,4-bis[4-(N,N-diisobutylamino)-2,6-dihydroxyphenyl] (squaraine) has a LUMO energy of 3.7 eV, and a HOMO energy of 5.4 eV. The materials listed in FIG. 3(b) may also comprise an electron blocking EBL in a squaraine/C₆₀ cell.

In some embodiments of the present disclosure, the electron blocking EBL thickness ranges from about 10 Å to about 1000 Å, such as from about 20 Å to about 500 Å, or even from about 30 Å to about 100 Å. It is understood that in certain embodiment, the electron blocking EBL thickness may range in 10 Å increments from 10 Å to about 100 Å.

Hole Blocking EBL

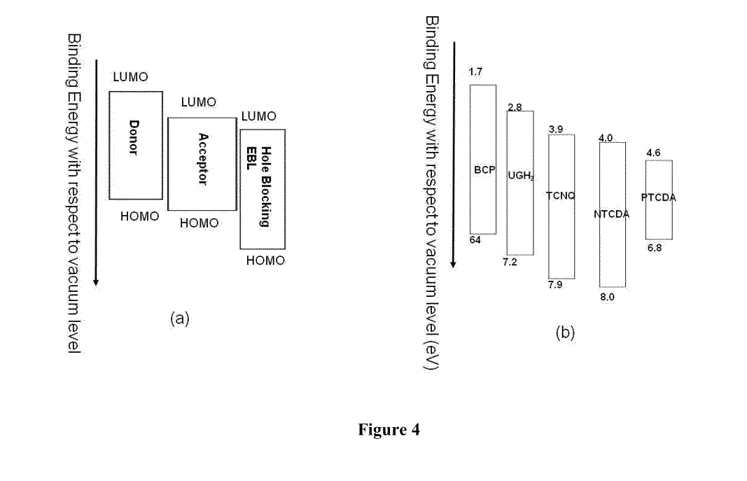

In at least one embodiment of the present disclosure, the hole blocking EBL is adjacent to the acceptor region. Usually, the hole leakage current Iₕ is small, due to the relatively large ΔE_{H} in most commonly used donor/acceptor pairs. However, when the hole leakage current Iₕ is dominating in a PV cell, a hole blocking EBL can be used to reduce the cell dark current and increase Voc. An energy level diagram of a structure comprising a hole blocking EBL in accordance with the present disclosure is shown in FIG. 4(a). To efficiently suppress the hole leakage current Iₕ without affecting the electron collection process, the hole blocking EBL should satisfy the following criteria:
1) hole blocking EBL has a lower HOMO energy level than the acceptor material;
2) hole blocking EBL does not introduce a large energy barrier for the electron collection at the acceptor/hole blocking EBL interface, for example the LUMO of the blocking layer is about equal to or lower than the LUMO of the acceptor; and
3) hole blocking EBL maintains a large interfacial gap at the interface with the acceptor material, as indicated by a smaller generation/recombination current than the generation/recombination current between the donor and acceptor, otherwise the generation/recombination current at the acceptor/hole blocking EBL interface may contribute significantly to the device dark current.

Acceptor materials according to the present disclosure include, but are not limited to, C₆₀ and 4,9,10-perylenetetracarboxylic bis-benzimidazole (PTCBI). Both of C₆₀ and PTCBI have a LUMO energy of 4.0 eV and a HOMO energy of 6.2 eV.

Suitable materials for the hole blocking EBL in a C₆₀ or PTCBI cell in accordance with the present disclosure include, but are not limited to, 2,9-dimethyl-4,7-diphenyl-1,10-phenanthroline (bathocuproine or BCP), naphthalene tetracarboxylic anhydride (NTCDA), p-bis(triphenylsilyl)benzene (UGH2), 3,4,9,10-perylenetetracarboxylic dianhydride (PTCDA), and 7,7,8,8,-tetracyanonequinodimethane (TCNQ) (FIG. 4(b)). The LUMO energy level of the hole blocking EBL may be high, for example if the cathode deposition introduces defect levels for electron transport. The hole blocking EBL according to the present disclosure also functions as an exciton blocking layer between the acceptor region and the cathode.

In some embodiments of the present disclosure, the hole blocking EBL thickness ranges from about 10 Å to about 1000 Å, such as from about 20 Å to about 500 Å, or even from about 30 Å to about 100 Å. It is understood that in certain embodiment, the hole blocking EBL thickness may range in 10 Å increments from 10 Å, to about 150 Å.

The device presently disclosed may provide for significant power conversion efficiency enhancement. For example, an ITO/tin (II) phthalocyanine (SnPc)/C₆₀/bathocuproine (BCP)/Al cell has high J_{sc} due to a high absorption coefficient in a large spectral range, but has a low power conversion efficiency due to a low open circuit voltage. Using an electron blocking EBL in a SnPC/C₆₀ cell may thus increase V_{oc}. In some embodiments of the present disclosure, the cell has low dark current and high VOC. In some embodiments, V_{OC} may be about two times greater by using an electron blocking EBL. In other embodiments, V_{OC} may be greater than two times greater by using an electron blocking EBL.

Stacked organic photosensitive optoelectronic devices are further contemplated herein. The stacked device according to the present disclosure may comprise a plurality of photosensitive optoelectronic subcells, wherein at least one subcell comprises two electrodes comprising an anode and a cathode in superposed relation; a donor region between the two electrodes, the donor region formed of a first photoconductive organic semiconductor material; an acceptor region between the two electrodes and adjacent to the donor region, the acceptor region formed of a second photoconductive organic semiconductor material; and at least one of an electron blocking layer and a hold blocking layer between the two electrodes, and adjacent to at least one of the donor region and the acceptor region. Such stack devices may be constructed in accord with the present disclosure to achieve high internal and external quantum efficiencies.

When the term “subcell” is used hereafter, it refers to an organic photosensitive optoelectronic construction which may include at least one of an electron blocking EBL and a hole blocking EBL in accordance with the present disclosure. When a subcell is used individually as a photosensitive optoelectronic device, it typically includes a complete set of electrodes, i.e., positive and negative. As disclosed herein, in some stacked configurations it is possible for adjacent subcells to utilize common, i.e., shared, electrode, charge transfer region or charge recombination zone. In other cases, adjacent subcells do not share common electrodes or charge transfer regions. The term “subcell” is disclosed herein to encompass the subunit construction regardless of whether each subunit has its own distinct electrodes or shares electrodes or charge transfer regions with adjacent subunits. Herein the terms “cell”, “subcell”, “unit”, “subunit”, “section”, and “subsection” are used interchangeably to refer a photoconductive region or set of regions and the adjoining electrodes or charge transfer regions. As used herein, the terms “stack”, “stacked”, “multisection” and “multicell” refer to any optoelectronic device with multiple regions of a photoconductive material separated by one or more electrode or charge transfer regions.

Since the stacked subcells of the solar cell may be fabricated using vacuum deposition techniques that allow external electrical connections to be made to the electrodes separating the subcells, each of the subcells in the device may be electrically connected either in parallel or in series, depending on whether the power and/or voltage generated by the PV cell is to be maximized. The improved external quantum efficiency that may be achieved for stacked PV cell embodiments of the present disclosure may also be attributed to the fact that the subcells of the stacked PV cell may be electrically connected in parallel since a parallel electrical configuration permits substantially higher fill factors to be realized than when the subcells are connected in series.

In the case when the PV cell is comprised of subcells electrically connected in series so as to produce a higher voltage device, the stacked PV cell may be fabricated so as to have each subcell producing approximately the same current so to reduce inefficiency. For example, if the incident radiation passes through in only one direction, the stacked subcells may have an increasing thickness with the outermost subcell, which is most directly exposed to the incident radiation, being the thinnest. Alternatively, if the subcells are superposed on a reflective surface, the thicknesses of the individual subcells may be adjusted to account for the total combined radiation admitted to each subcell from the original and reflected directions.

Further, it may be desirable to have a direct current power supply capable of producing a number of different voltages. For this application, external connections to intervening electrodes could have great utility. Accordingly, in addition to being capable of providing the maximum voltage that is generated across the entire set of subcells, an exemplary embodiment the stacked PV cells of the present disclosure may also be used to provide multiple voltages from a single power source by tapping a selected voltage from a selected subset of subcells.

Representative embodiments of the present disclosure may also comprise transparent charge transfer regions. As described herein charge transfer layers are distinguished from acceptor and donor regions/materials by the fact that charge transfer regions are frequently, but not necessarily, inorganic and they are generally chosen not to be photoconductively active.

The organic photosensitive optoelectronic device disclosed herein may be useful in a number of photovoltaic applications. In at least one embodiment, the device is an organic photodetector. In at least one embodiment, the device is an organic solar cell.

### EXAMPLES

The present disclosure may be understood more readily by reference to the following detailed description of exemplary embodiments and the working examples. It is understood that other embodiments will become apparent to those skilled in the art in view of the description and examples disclosed in this specification.

### Example 1

Devices were prepared on 1500-Å-thick layers of ITO (sheet resistance of 15 Ω/cm²) precoated onto glass substrates. The solvent-cleaned ITO surface was treated in ultraviolet/O₃⁻ for 5 min immediately before loading into a high vacuum chamber (base pressure <4×10⁻⁷ Torr), where the organic layers and a 100-Å-thick Al cathode were sequentially deposited via thermal evaporation. The deposition rate of the purified organic layers was ˜Å/s. (Laudise et al., J. Cryst. Growth, 187, 449 (1998).) The Al cathode was evaporated through a shadow mask with 1 mm-diameter openings to define the device active area. The current density versus voltage (J-V) characteristics were measured in the dark and under simulated AM1.5G solar illumination. Illumination intensity and quantum efficiency measurements were conducted using standard methods employing an NREL calibrated Si detector. (ASTM Standards E1021, E948, and E973, 1998.)

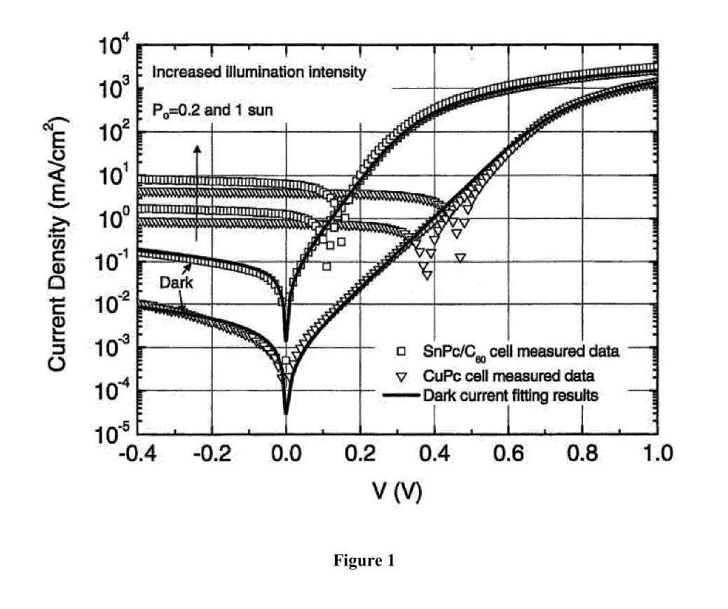

FIG. 1 shows the current density-voltage (J-V) characteristics of an ITO/SnPc (100 Å)/C₆₀ (400 Å)/bathocuproine (BCP, 100 Å)/Al PV cell, an ITO/CuPc (200 Å)/C₆₀ (400 Å)/BCP (100 Å)/Al PV control, and the dark J-V fitting results. Compared to the CuPc cell, the SnPc-based device has a higher dark current, which can be understood in terms of differences in energy levels between. the two structures. The highest occupied molecular orbital (HOMO) energies of both SnPc and CuPc are at 5.2 eV below the vacuum level. (Kahn et al., J. Polymer Sci. B, 41, 2529-2548 (2003); Rand et al., Appl. Phys. Lett., 87, 233508 (2005).) The lowest unoccupied molecular orbital (LUMO) energy for CuPc is 3.2 eV, as measured by inverse photoemission spectroscopy (IPES). For SnPc, the LUMO energy is estimated from the optical band gap to be 3.8 eV. Since the LUMO energy of C₆₀ is 4.0 eV (Shirley et al., Phys. Rev. Lett., 71(1), 133 (1993), this results in a 0.8 eV barrier to electron transport from the C₆₀ acceptor to the anode for a CuPc/C₆₀ cell, but only 0.2 eV for the SnPc/C60 device. As a result, the dark current in the CuPc/C₆₀ cell arises mainly from generation and recombination at the CuPc/C₆₀ heterojunction, whereas in the SnPc/C60 cell, the electron leakage current from cathode to anode dominates.

From Eq. (1), fits to the dark J-V characteristics in FIG. 1 yield n=1.5 and Jₛ=5.1×10⁻² mA/cm² for the SnPc-based cell, and n=2.0 and Jₛ=6.3×10⁻⁴ mA/cm² for the cell employing CuPc as the donor. V_{OC} may be calculated using Eq. (2) assuming a constant Jₚₕ (V)=J_{SC} (short circuit current). At one sun illumination, V_{OC}=0.19V for SnPc and 0.46V for the CuPc cell, ignoring the small parallel resistance term. The calculated Voc from dark current fitting parameters and J_{sc} are consistent with measured values of 0.16±0.01V and 0.46±0.01V, respectively.

### Example 2

To decrease J_{S}, and hence increase V_{OC} in a SnPc/C₆₀ cell, an electron blocking EBL was inserted between the anode and the SnPc donor layer described in Example 1. According to the energy level diagram in the inset of FIG. 2, the electron blocking EBL should (i) have a higher LUMO energy than the donor LUMO, (ii) have a relatively high hole mobility, and (iii) limit dark current due to generation and recombination at the interface with the donor resulting from a small electron blocking EBL (HOMO) to donor (LUMO) “interfacial gap” energy. Following these considerations, the inorganic material MoO₃, and boron subphthalocyanine chloride (SubPc) and CuPc were employed as electron blocking EBLs. (Mutolo et al., J. Am. Chem. Soc., 128, 8108 (2006)) According to their respective energy levels (FIG. 2), they all effectively impede electron current from the donor to the anode contact. MoO₃ has previously been used in polymer PV cells to prevent reactions between ITO and the polymer PV active layers (Shrotriya et al., Appl. Phys. Lett. 88, 073508 (2006)).

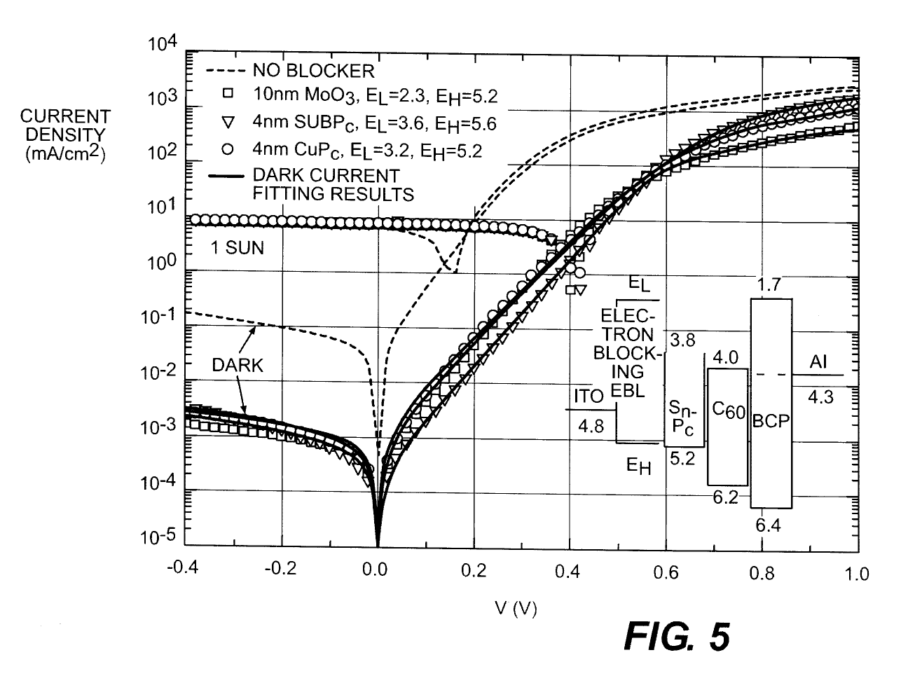

Experiments were conducted employing an electron blocking EBL in an ITO/SnPc (100 Å)/C₆₀ (400 Å)/BCP (100 Å)/Al PV cell. FIG. 5 shows the J-V characteristics of the cell with a 100 Å thick MoO₃ electron blocking EBL, a 40 Å thick SubPc EBL, and a 40 Å CuPc electron blocking EBL. The characteristics of SnPC/C₆₀ without a blocker are also shown for comparison. The electron blocking EBLs were found to significantly suppress dark current. V_{oc} measured under one sun illumination increased to >0.40 V in all devices comprising an electron blocking EBL.

The performances of all devices are summarized in Table 1. The values for V_{OC}, J_{SC}, fill factor (FF), and power conversion efficiency (ηₚ) were measured at one sun standard AM1.5G solar illumination. The high V_{OC} lead to a concomitant increase in power conversion efficiency, from (0.45±0.1) % for a SnPc device without the electron blocking EBL, to a maximum of (2.1±0.1) % with the electron blocking EBL. Note that the SubPc electron blocking EBL introduces an energy barrier to holes in addition to electrons. Hence, increasing its thickness from 20 Å to 40 Å leads to a decrease in fill factor, possibly due to the small barrier to hole conduction (0.4 eV; see FIG. 5 insert), and hence a slight decrease in power conversion efficiency.

TABLE 1
Performance of Blocker/SnPc/C₆₀/BCPsolar cells at 1 sun, AM1.5 illumination.

| | V_{OC} | | J_{SC} | n_{P} | J_{S} | | Rₛ | Rₚ | Calculated |
|---|---|---|---|---|---|---|---|---|---|
| | (V) | FF | (mA/cm²) | (%) | (mA/cm²) | n | (Ωcm²) | (Ωcm²) | V_{OC} (V) |
| No blocker | 0.16 | 0.44 | 6.4 | 0.45 | 5.1 × 10⁻² | 1.5 | 0.19 | 2.9 × 10³ | 0.19 |
| 30 Å MoO₃ | 0.37 | 0.62 | 7.4 | 1.7 | 1.2 × 10⁻³ | 1.7 | 0.19 | 1.1 × 10⁵ | 0.39 |
| 100 Å MoO₃ | 0.40 | 0.63 | 7.6 | 1.9 | 6.0 × 10⁻⁴ | 1.7 | 1.2 | 1.6 × 10⁵ | 0.42 |
| 300 Å MoO₃ | 0.42 | 0.61 | 7.4 | 1.9 | 5.5 × 10⁻⁴ | 1.8 | 2.2 | 3.5 × 10⁵ | 0.45 |
| 20 Å SubPc | 0.40 | 0.62 | 8.4 | 2.1 | 5.9 × 10⁻⁴ | 1.7 | 0.17 | 1.4 × 10⁵ | 0.42 |
| 40 Å SubPc | 0.41 | 0.55 | 8.8 | 2.0 | 3.1 × 10⁻⁴ | 1.8 | 0.14 | 1.4 × 10⁵ | 0.44 |
| 40 Å CuPc | 0.41 | 0.58 | 7.9 | 1.9 | 9.8 × 10⁻⁴ | 1.9 | 0.27 | 1.4 × 10⁵ | 0.44 |

Equation (1) was used to fit the dark current of all devices with the resulting fitting parameters listed in Table 1. When the MoO₃ layer thickness exceeded 100 Å, or the SubPc layer thickness was >20 Å, J_{S} was only 1% that of devices lacking the blocking layers. If the electron blocking EBL thickness was further increased, the additional decrease in J_{S} was marginal, indicating that these thin layers effectively eliminated electron leakage. As Table 1 indicates, the calculated V_{OC} values were consistent with the measured values for all devices.

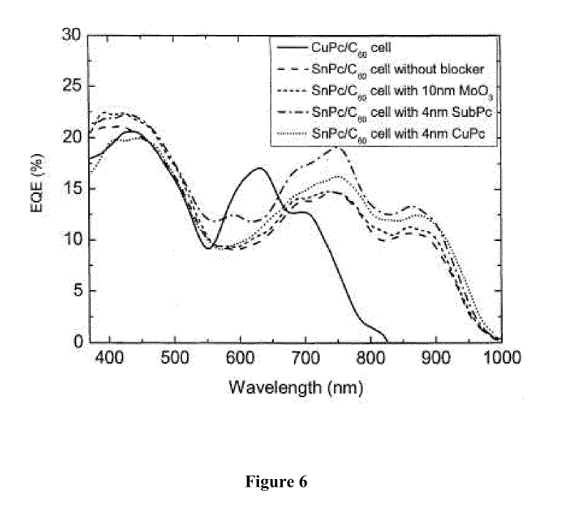

FIG. 6 shows the external quantum efficiency (EQE) spectra of an ITO/CuPc (200 Å)/C₆₀ (400 Å)/BCP (100 Å)/Al (1000 Å) photovoltaic (PV) cell, an ITO/SnPc (100 Å)/C₆₀ (400 Å)/BCP (100 Å)/Al PV cell without an electron blocking EBL, with a MoO₃ electron blocking EBL, with a SubPc electron blocking EBL, and with a CuPc electron blocking EBL. The EQE of the CuPc cell decreased to <10% at λ>730 nm, whereas the EQE values of all SnPc cells were >10% at λ<900 nm. The efficiencies of devices employing a MoO₃ electron blocking EBL were the same as those without an electron blocking EBL, suggesting that the increased power conversion efficiency was due to the reduced leakage current. In addition, devices with a SubPc electron blocking EBL had a higher efficiency than those with MoO₃ due to the increased absorption in the green spectral region and subsequent exciton generation from SnPc.

The specification and examples disclosed herein are intended to be considered as exemplary only, with a true scope and spirit of the invention being indicated in the following claims.

Other than in the examples, or where otherwise indicated, all numbers expressing quantities of ingredients, reaction conditions, analytical measurements, and so forth used in the specification and claims are to be understood as being modified in all instances by the term “about.” Accordingly, unless indicated to the contrary, the numerical parameters set forth in the specification and attached claims are approximations that may vary depending upon the desired properties sought to be obtained by the present disclosure. At the very least, and not as an attempt to limit the application of the doctrine of equivalents to the scope of the claims, each numerical parameter should be construed in light of the number of significant digits and ordinary rounding approaches.

Notwithstanding that the numerical ranges and parameters setting forth the broad scope of the disclosure are approximations, unless otherwise indicated the numerical values set forth in the specific examples are reported as precisely as possible. Any numerical value, however, inherently contains certain errors necessarily resulting from the standard deviation found in their respective testing measurements.

What is claimed is:

1. An organic photosensitive optoelectronic device comprising:
two electrodes comprising an anode and a cathode in superposed relation;
at least one donor material and
at least one acceptor material,
wherein said donor material and acceptor material form a photo-active region between the two electrodes;
at least one electron blocking layer or hole blocking layer located between the two electrodes,
wherein the electron blocking layer and the hole blocking layer comprise at least one material chosen from organic semiconductors, inorganic semiconductors, polymers, metal oxides, or combinations thereof.

2. The device of claim 1, wherein the electron blocking layer comprises at least one organic semiconducting material chosen from tris-(8-hydroxyquinolinato)aluminium(III) (Alq3), N,N′-bis(3-methylphenyl)-(1,1′-biphenyl)-4′-diamine (TPD), 4,4′-bis[N-(naphthyl)-N-phenyl-amino]biphenyl (NPD), subphthalocyanine (SubPc), pentacene, squaraine, copper phthalocyanine (CuPc), zinc phthalocyanine (ZnPc), chloroaluminum phthalocyanine (ClAlPc), tris(2-phenylpyridine) (Ir(ppy)₃).

3. The device of claim 1, wherein the electron blocking layer comprises at least one metal oxide of Cu, Al, Sn, Ni, W, Ti, Mg, In, Mo, Zn, and combinations thereof.

4. The device of claim 1, wherein the electron blocking layer comprises at least one of Si, II-VI, and III-V semiconductor material.

5. The device of claim 1, wherein the hole blocking layer comprises at least one organic semiconducting material chosen from naphthalene tetracarboxylic anhydride (NTCDA), p-bis(triphenylsilyl)benzene (UGH2), 3,4,9,10-perylenetetracarboxylic dianhydride (PTCDA), and 7,7,8,8,-tetracyanonequinodimethane (TCNQ).

6. The device of claim 1, wherein the hole blocking layer comprises at least one inorganic material chosen from TiO₂, GaN, ZnS, ZnO, ZnSe, SrTiO₃, KaTiO₃, BaTiO₃, MnTiO₃, PbO, WO₃, and SnO₂.

7. The device of claim 1, wherein the electron blocking is in contact with the donor region.

8. The device of claim 1, wherein the hole blocking layer is in contact with the acceptor region.

9. The device of claim 1, wherein the device comprises both an electron blocking and a hole blocking layer.

10. The device of claim 1, wherein the donor region comprises at least one material chosen from CuPc, SnPc, and squaraine.

11. The device of claim 1, wherein the acceptor region comprises at least one material chosen from C₆₀ and PTCBI.

12. The device of claim 1, wherein the first photoconductive organic semiconductor material and the second photoconductive organic semiconductor material are selected to have spectral sensitivity in the visible spectrum.

13. The device of claim 1, wherein the first photoconductive organic semiconductor material and the second photoconductive organic semiconductor material are at least partially mixed.

14. The device of claim 1, wherein the photo-active region forms at least one of a mixed heterojunction, planar heterojunction, bulk heterojunction, nano crystalline-bulk heterojunction, and hybrid planar-mixed heterojunction.

15. The device of claim 1, wherein the electron blocking comprises SubPc, CuPc, or MoO₃ and has a thickness ranging from about 30 Å to about 100 Å.

16. The device of claim 1, wherein the hole blocking has a thickness ranging from 20 Å to 500 Å.

17. The device of claim 1, wherein the donor region comprises at least one material chosen from CuPc and SnPc, the acceptor region comprises C₆₀, and the electron blocking layer comprises MoO₃.

18. The device of claim 1, wherein the device is an organic photodetector.

19. The device of claim 1, wherein the device is an organic solar cell.

20. A stacked organic photosensitive optoelectronic device comprising a plurality of photosensitive optoelectronic subcells, wherein at least one subcell comprises:
two electrodes comprising an anode and a cathode in superposed relation;
at least one donor material and
at least one acceptor material,
wherein said donor material and acceptor material form a photo-active region between the two electrodes;
at least one electron blocking or hole blocking layer located between the two electrodes,
wherein the electron blocking layer and the hole blocking layer comprise at least one material chosen from organic semiconductors, inorganic semiconductors, polymers, metal oxides, or combinations thereof.

21. The stacked organic photosensitive optoelectronic device of claim 20, wherein the electron blocking layer comprises at least one organic semiconducting material chosen from tris-(8-hydroxyquinolinato)aluminium(III) (Alq3), N,N′-bis(3-methylphenyl)-(1,1′-biphenyl)-4′-diamine (TPD), 4,4′-bis[N-(naphthyl)-N-phenyl-amino]biphenyl (NPD), subphthalocyanine (SubPc), pentacene, squaraine, copper phthalocyanine (CuPc), zinc phthalocyanine (ZnPc), chloroaluminum phthalocyanine (ClAlPc), tris(2-phenylpyridine) (Ir(ppy)₃).

22. The stacked organic photosensitive optoelectronic device of claim 20, wherein the electron blocking layer comprises at least one metal oxide of Cu, Al, Sn, Ni, W, Ti, Mg, In, Mo, Zn, and combinations thereof.

23. The stacked organic photosensitive optoelectronic device of claim 20, wherein the electron blocking layer comprises at least one Si, II-VI, III-V semiconductor material.

24. The stacked organic photosensitive optoelectronic device of claim 20, wherein the hole blocking layer comprises at least one organic semiconducting material chosen from naphthalene tetracarboxylic anhydride (NTCDA), p-bis(triphenylsilyl)benzene (UGH2), 3,4,9,10-perylenetetracarboxylic dianhydride (PTCDA), and 7,7,8,8,-tetracyanonequinodimethane (TCNQ).

25. The stacked organic photosensitive optoelectronic device of claim 20, wherein the hole blocking layer comprises at least one inorganic material chosen from TiO₂, GaN, ZnS, ZnO, ZnSe, SrTiO₃, KaTiO₃, BaTiO₃, MnTiO₃, PbO, WO₃, and SnO₂.

26. A method of increasing the power conversion efficiency of a photosensitive optoelectronic device by reducing the dark current comprising incorporating in the device
at least one electron blocking or hole blocking layer,
wherein the electron blocking layer or hole blocking layer comprises at least one material chosen from organic semiconductors, inorganic semiconductors, polymers, metal oxides, or combinations thereof.

27. The method of claim 26, wherein the electron blocking layer comprises at least one organic semiconducting material chosen from tris-(8-hydroxyquinolinato)aluminium(III) (Alq3), N,N′-bis(3-methylphenyl)-(1,1′-biphenyl)-4′-diamine (TPD), 4,4′-bis[N-(naphthyl)-N-phenyl-amino]biphenyl (NPD), subphthalocyanine (SubPc), pentacene, squaraine, copper phthalocyanine (CuPc), zinc phthalocyanine (ZnPc), chloroaluminum phthalocyanine (ClAlPc), tris(2-phenylpyridine) (Ir(ppy)₃).

27. The method of claim 26, wherein the electron blocking layer comprises at least one metal oxide of Cu, Al, Sn, Ni, W, Ti, Mg, In, Mo, Zn, and combinations thereof.

28. The method of claim 26, wherein the electron blocking layer comprises at least one of Si, II-VI, and III-V semiconductor materials.

29. The method of claim 26, wherein the hole blocking layer comprises at least one organic semiconducting material chosen from naphthalene tetracarboxylic anhydride (NTCDA), p-bis(triphenylsilyl)benzene (UGH2), 3,4,9,10-perylenetetracarboxylic dianhydride (PTCDA), and 7,7,8,8,-tetracyanonequinodimethane (TCNQ).

30. The method of claim 26, wherein the hole blocking layer comprises at least one inorganic material chosen from TiO₂, GaN, ZnS, ZnO, ZnSe, SrTiO₃, KaTiO₃, BaTiO₃, MnTiO₃, PbO, WO₃, and SnO₂.
